(19) United States
(12) Patent Application Publication
(10) Pub. No.: US 2017/0191183 A1
(43) Pub. Date: Jul. 6, 2017

(54) METHOD OF MANUFACTURING SILICON CARBIDE INGOT, SILICON CARBIDE SEED SUBSTRATE, SILICON CARBIDE SUBSTRATE, SEMICONDUCTOR DEVICE AND METHOD OF MANUFACTURING SEMICONDUCTOR DEVICE

(71) Applicant: SUMITOMO ELECTRIC INDUSTRIES, LTD., Osaka-shi, Osaka (JP)

(72) Inventor: Makoto SASAKI, Itami-shi, Hyogo (JP)

(21) Appl. No.: 15/313,571

(22) PCT Filed: May 21, 2015
(86) PCT No.: PCT/JP2015/064586

§ 371 Date: Nov. 23, 2016

(30) Foreign Application Priority Data
May 29, 2014 (JP) 2014-111174
Apr. 3, 2015 (JP) PCT/JP2015/060634

(51) Int. Cl. C30B 23/02; H01L 29/16; C30B 33/00; C30B 29/36; C30B 23/06

(52) U.S. Cl. CPC C30B 23/025; C30B 29/36; C30B 23/063; C30B 33/00; H01L 29/1608

(57) ABSTRACT

A method of manufacturing a silicon carbide ingot includes the steps of: preparing a silicon carbide seed substrate having a first main surface and a second main surface located opposite the first main surface; forming a metal carbide film on the second main surface at a temperature of not more than 2000° C.; and growing a silicon carbide single crystal on the first main surface by sublimation, while supporting the silicon carbide seed substrate having the metal carbide film formed thereon by a supporting member. In the growing step, a supported portion of the surface of the silicon carbide seed substrate supported by the supporting member is in a region other than a region where the metal carbide film has been formed.

### TECHNICAL FIELD

The present disclosure relates to methods of manufacturing silicon carbide (SiC) ingots, silicon carbide seed substrates, silicon carbide substrates, semiconductor devices and methods of manufacturing the semiconductor devices.

### BACKGROUND ART

Most SiC ingots (single crystals) are manufactured by sublimation (also referred to as the “modified Lely method”) [see Japanese Patent Laying-Open No. 2001-139394 (PTD 1) and Japanese Patent Laying-Open No. 2008-280196 (PTD 2), for example].

### CITATION LIST

### Patent Documents

### PTD 1: Japanese Patent Laying-Open No. 2001-139394

### PTD 2: Japanese Patent Laying-Open No. 2008-280196

### SUMMARY OF INVENTION

### Technical Problem

An object of the present disclosure is to provide a silicon carbide ingot with a low number of crystal defects, a silicon carbide seed substrate that can be used in manufacturing the silicon carbide ingot, a silicon carbide substrate obtained from the silicon carbide ingot, and a semiconductor device including the silicon carbide substrate.

### Solution to Problem

A method of manufacturing a silicon carbide ingot according to one aspect of the present disclosure includes the steps of: preparing a silicon carbide seed substrate having a first main surface and a second main surface located opposite the first main surface; forming a metal carbide film on the second main surface at a temperature of not more than 2000° C.; and growing a silicon carbide single crystal on the first main surface by sublimation, while supporting the silicon carbide seed substrate having the metal carbide film formed thereon by a supporting member, in the growing step, a supported portion of the surface of the silicon carbide seed substrate supported by the supporting member being in a region other than a region where the metal carbide film has been formed.

A silicon carbide seed substrate according to one aspect of the present disclosure includes a first main surface and a second main surface located opposite the first main surface, the first main surface being a crystal growth surface, the second main surface having a metal carbide film thereon, the metal carbide film including at least one of titanium carbide, vanadium carbide and zirconium carbide.

A semiconductor device according to one aspect of the present disclosure includes a silicon carbide substrate including at least one selected from the group of metal elements consisting of titanium, vanadium and zirconium, a concentration of the metal element being not less than 0.01 ppm and not more than 0.1 ppm.

### Advantageous Effects of Invention

According to above, there are provided a silicon carbide ingot with a low number of crystal defects, a silicon carbide seed substrate that can be used in manufacturing the silicon carbide ingot, a silicon carbide substrate obtained from the silicon carbide ingot, and a semiconductor device including the silicon carbide substrate.

### BRIEF DESCRIPTION OF DRAWINGS

FIG. 1 is a flowchart showing an overview of a method of manufacturing a silicon carbide ingot according to one aspect of the present disclosure.

FIG. 2 is a flowchart showing an example of a step of forming a metal carbide film according to one aspect of the present disclosure.

FIG. 3 is a flowchart showing an example of a step of carbonizing a metal film according to one aspect of the present disclosure.

FIG. 4 is a schematic cross-sectional view illustrating an example of a step of growing a silicon carbide single crystal according to one aspect of the present disclosure.

FIG. 5 is a schematic cross-sectional view illustrating another example of the step of growing a silicon carbide single crystal according to one aspect of the present disclosure.

FIG. 6 is a schematic plan view illustrating an example of supported portions of a surface of a silicon carbide seed substrate supported by a supporting member according to one aspect of the present disclosure.

FIG. 7 is a schematic plan view illustrating another example of the supported portion of the surface of the silicon carbide seed substrate supported by the supporting member according to one aspect of the present disclosure.

FIG. 8 is a schematic cross-sectional view illustrating an example of the step of carbonizing a metal film according to one aspect of the present disclosure.

FIG. 9 is a schematic diagram showing an example of a silicon carbide substrate according to one aspect of the present disclosure.

FIG. 10 is a schematic cross-sectional view showing an example of the configuration of a semiconductor device according to one aspect of the present disclosure.

FIG. 11 is a flowchart showing an overview of a method of manufacturing the semiconductor device according to one aspect of the present disclosure.

FIG. 12 is a schematic cross-sectional view showing an example of a silicon carbide epitaxial substrate according to one aspect of the present disclosure.

FIG. 13 is a schematic cross-sectional view illustrating an ion implantation step.

FIG. 14 is a schematic cross-sectional view illustrating a gate oxide film formation step and an electrode formation step.

FIG. 15 is a schematic cross-sectional view illustrating an interlayer insulating film formation step and an electrode formation step.

### DESCRIPTION OF EMBODIMENTS

### Description of Embodiments of the Present Disclosure

Embodiments of the present disclosure will be described first in list form. In the following description, the same or corresponding elements are designated by the same reference signs and are not described repeatedly. Regarding crystallographic indications in the present specification, an individual orientation is represented by [ ], a group orientation is represented by < >, an individual plane is represented by ( ) and a group plane is represented by { }. In addition, a negative crystallographic index is normally expressed by putting “-” (bar) above a numeral, but is expressed by putting a negative sign before the numeral in the present specification.

Sublimation is a crystal growing process of sublimating a source material under high temperature, and recrystallizing the sublimated source material on a seed crystal. Usually in this process, the source material is contained in a lower portion of a growth container (a crucible made of graphite, for example), and the seed crystal is adhered and fixed to a supporting member (a lid of the crucible, for example) located in an upper portion of the growth container. For the fixing of the seed crystal, a seed crystal fixing agent obtained by dispersing graphite fine particles in an organic solvent is widely used (see PTD 1, for example).

The seed crystal fixing agent is carbonized by being heated, and serves as a heat-resistant adhesive layer. Accordingly, the seed crystal can be retained on the supporting member without falling even in a high-temperature environment (about 2300° C.) in the growth container. However, bubbles (voids) produced during volatilization of the solvent may remain in such an adhesive layer. If the voids are present in the adhesive layer, sublimation occurs from an adhesive surface (backside surface) of the seed crystal through the voids toward the supporting member (so-called backside sublimation), causing desorption of some of the elements from the backside surface. Roughness (defects) of the backside surface caused by the element desorption propagates to a growth surface, then further to a grown crystal, and manifests itself as micropipe defects.

To address such a problem, PTD 2 discloses a method of fixing a seed crystal to a supporting member by titanium carbide. According to PTD 2, there are no voids in an adhesive layer made of titanium carbide, so that the backside sublimation can be prevented.

However, there is still room for improvement in this method. That is, since the seed crystal (SiC) and the supporting member (typically C) have different thermal expansion coefficients, exposure of the seed crystal and the supporting member to a high-temperature environment with the backside surface of the seed crystal being fixed (constrained) to the supporting member causes thermal stress in the seed crystal and the single crystal on the growth surface due to the difference in the amount of expansion between the seed crystal and the supporting member, thus allowing the occurrence of defects (dislocation defects, for example) resulting from this thermal stress.

The present inventor conceived that the problems noted above could be solved by allowing for free thermal expansion of the seed crystal without constraining the seed crystal to the supporting member, and conducted further studies based on this concept to complete one aspect of the present disclosure.

That is, [1] a method of manufacturing a silicon carbide ingot according to one aspect of the present disclosure includes the steps of preparing a silicon carbide seed substrate having a first main surface and a second main surface located opposite the first main surface; forming a metal carbide film on the second main surface at a temperature of not more than 2000° C.; and growing a silicon carbide single crystal on the first main surface by sublimation, while supporting the silicon carbide seed substrate having the metal carbide film formed thereon by a supporting member, in the growing step, a supported portion of the surface of the silicon carbide seed substrate supported by the supporting member being in a region other than a region where the metal carbide film has been formed.

In the above manufacturing method, the SiC seed substrate (seed crystal) is supported at a portion other than the second main surface (backside surface). The second main surface is not constrained and the SiC seed substrate can thermally expand freely, thereby relieving thermal stress that occurs in the SiC seed substrate and SiC single crystal (grown crystal). Thus, the occurrence of defects resulting from the thermal stress can be suppressed.

Furthermore, while a gap is usually created between the second main surface and the supporting member in such a mode, resulting in backside sublimation, such backside sublimation is also suppressed in the above manufacturing method since the metal carbide film is formed as a sublimation preventing film on the second main surface. Here, the melting point of the metal carbide film is preferably higher than the sublimation temperature of SiC. In addition, the metal carbide film is formed at not more than 2000° C., that is, a temperature of less than the sublimation temperature of SiC. Accordingly, the sublimation of an element from the SiC seed substrate, which in turn roughens the surface of the substrate, is suppressed during the formation of the metal carbide film.

According to the above manufacturing method, therefore, the SiC single crystal with a low number of crystal defects can be grown on the first main surface (crystal growth surface) while the occurrence of backside sublimation and thermal stress is simultaneously suppressed.

[2] The metal carbide film may include at least one of titanium carbide, vanadium carbide and zirconium carbide.

Since the metal carbide film including titanium carbide (TiC), vanadium carbide (VC), zirconium carbide (ZrC) has a melting point higher than the sublimation temperature of SiC, and can be a dense film, the backside sublimation can be suppressed.

[3] The step of forming a metal carbide film may include the steps of forming a metal film on the second main surface, and carbonizing the metal film. This is because the metal carbide film can be easily formed.

[4] The step of carbonizing the metal film may include the steps of placing the silicon carbide seed substrate on a carbon base, with the first main surface facing downward, and heating the metal film while supplying carbon to the metal film. This is because the metal carbide film can be easily formed while the first main surface serving as the growth surface is protected.

[5] The step of forming a metal carbide film may further include the step of, after the step of carbonizing the metal film, planarizing the metal carbide film. This is because excessive carbon can be reduced.

[6] In the growing step, the silicon carbide seed substrate may be disposed above and at a distance from the source material, the first main surface may face the source material, and the supported portion may be at the end of the first main surface. This is because, according to such a mode, the SiC single crystal can be grown on the first main surface with the SiC seed substrate not being constrained.

[7] A silicon carbide seed substrate according to one aspect of the present disclosure includes a first main surface and a second main surface located opposite the first main surface, the first main surface being a crystal growth surface, the second main surface having a metal carbide film thereon, the metal carbide film including at least one of titanium carbide, vanadium carbide and zirconium carbide.

This SiC seed substrate has the metal carbide film including at least one of TiC, VC and ZrC on the second main surface (backside surface), and thus can be used for a method of manufacturing a SiC ingot which does not use a seed crystal fixing agent.

[8] A film thickness of the metal carbide film may be not less than 0.1 μm and not more than 1.0 mm. This is because the backside sublimation can be suppressed while excessive cost is avoided.

[9] A coefficient of variation of the film thickness of the metal carbide film may be not more than 20%. This is because the thermal stress can be relieved.

[10] A method of manufacturing a silicon carbide ingot according to one aspect of the present disclosure includes the steps of: preparing the silicon carbide seed substrate according to any one of [7] to [9] above; and growing a silicon carbide single crystal on the first main surface by sublimation, while supporting the silicon carbide seed substrate by a supporting member, in the growing step, a supported portion of the surface of the silicon carbide seed substrate supported by the supporting member being in a region other than a region where the metal carbide film has been formed.

According to this manufacturing method, the SiC single crystal can be grown on the first main surface while the backside sublimation is suppressed and free expansion of the SiC seed substrate is not hindered. Thus, a SiC ingot with a low number of crystal defects can be manufactured.

[11] A silicon carbide substrate according to one aspect of the present disclosure is a substrate obtained by slicing the silicon carbide ingot which has been obtained with the manufacturing method according to [10] above, the substrate including a metal element forming the metal carbide film, a concentration of the metal element being not less than 0.01 ppm and not more than 0.1 ppm.

This SiC substrate is obtained by slicing a SiC ingot grown on the first main surface of the SiC seed substrate according to any one of [7] to [9] above. The SiC substrate thus includes the metal element forming the metal carbide film formed on the second main surface (backside surface) of the SiC seed substrate. This SiC substrate has suppressed backside sublimation and relaxed thermal stress during growth, and thus has a low number of defects and high crystal quality. In addition, the metal element within the above concentration range is considered to have little influence on the performance of the semiconductor device. Accordingly, this SiC substrate may help improve the performance of the semiconductor device. It should be noted that above “ppm” refers to a “mass fraction.”

[12] A semiconductor device according to one aspect of the present disclosure includes a silicon carbide substrate including at least one selected from the group of metal elements consisting of titanium, vanadium and zirconium, a concentration of the metal element being not less than 0.01 ppm and not more than 0.1 ppm.

[13] In [12] above, the silicon carbide substrate may be a semi-insulating substrate. The semi-insulating substrate as used herein refers to a substrate having a resistivity of not less than 10⁵ Ω·cm. The upper limit of the resistivity may be 10¹⁷ Ω·cm, for example. The concentration of an n type impurity in the semi-insulating substrate may be not less than 0 cm⁻³ and less than 10¹⁷ cm⁻³. The concentration of a p type impurity in the semi-insulating substrate may be not less than 0 cm⁻³ and less than 10¹⁷ cm⁻³.

[14] In [12] above, the silicon carbide substrate may be an n type substrate. The concentration of an n type impurity in the n type substrate may be not less than 10¹⁷ cm⁻³, for example. The upper limit of the concentration of then type impurity may be 10²⁰ cm⁻³, for example.

[15] In [12] above, the silicon carbide substrate may be a p type substrate. The concentration of a p type impurity in the p type substrate may be not less than 10¹⁷ cm⁻³, for example. The upper limit of the concentration of the p type impurity may be 10²⁰ cm⁻³, for example.

[16] A method of manufacturing a semiconductor device according to one aspect of the present disclosure includes the steps of: preparing the silicon carbide substrate according to [11] above; and processing the silicon carbide substrate.

### Details of Embodiments of the Present Disclosure

While embodiments of the present disclosure (hereinafter also referred to as “the present embodiment”) will now be described in detail, the present embodiment is not limited as such.

[Method of Manufacturing Silicon Carbide Ingot]

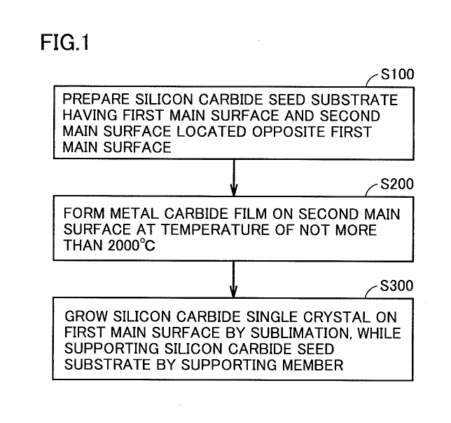

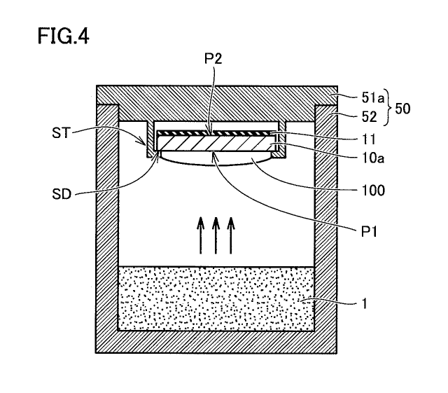

FIG. 1 is a flowchart showing an overview of a manufacturing method of the present embodiment. As shown in FIG. 1, this manufacturing method includes a step of preparing a SiC seed substrate 10a (S100), a step of forming a metal carbide film 11 (S200), and a step of growing a SiC single crystal 100 (S300). FIG. 4 is a schematic cross-sectional view illustrating the step of growing SiC single crystal 100. As shown in FIG. 4, in the manufacturing method of the present embodiment, metal carbide film 11 is formed on a backside surface (second main surface P2) of SiC seed substrate 10a, and SiC single crystal 100 is grown on a growth surface (first main surface P1), with second main surface P2 not being constrained and free thermal expansion of SiC seed substrate 10a not being hindered. This manufacturing method can suppress backside sublimation by metal carbide film 11, and can relieve thermal stress that occurs in SiC seed substrate 10a or SiC single crystal 100, thereby manufacturing SiC single crystal 100, namely, a SiC ingot, with a low number of crystal defects. In addition, since metal carbide film 11 is less likely to be vaporized than SiC, a metal element included in metal carbide film 11 is less likely to be incorporated into SiC single crystal 100. Each step will now be described.

<Step of Preparing Silicon Carbide Seed Substrate: S100>

SiC seed substrate 10a is prepared in this step. SiC seed substrate 10a has first main surface P1 and second main surface P2 located opposite first main surface P1. First main surface P1 is a crystal growth surface, and second main surface P2 is a backside surface thereof. First main surface P1 may be on the (0001) plane [so-called Si face], or on the (000-1) plane [so-called C face], for example.

SiC seed substrate 10a may be prepared by slicing a SiC ingot having a polytype of 4H, 6H, for example, into pieces of a certain thickness. The polytype of 4H is particularly useful for a semiconductor device. Here, it is desirable that the slicing be done such that first main surface P1 of SiC seed substrate 10a is inclined at not less than 1° and not more than 10° with respect to a {0001} plane. That is, it is desirable that SiC seed substrate 10a have an off angle of not less than 1° and not more than 10° with respect to the {0001} plane. This is because crystal defects such as basal plane dislocations can be suppressed by limiting the off angle of SiC seed substrate 10a in this manner. This off angle is more preferably not less than 1° and not more than 8°, and particularly preferably not less than 2° and not more than 8°. The off direction is a <11-20> direction, for example.

The planar shape of SiC seed substrate 10a is circular, for example. The diameter of SiC seed substrate 10a is not less than 25 mm, for example, preferably not less than 100 mm (not less than 4 inches, for example), and more preferably not less than 150 mm (not less than 6 inches, for example). The larger the diameter of SiC seed substrate 10a, the larger the diameter of a SiC ingot that can be manufactured. Consequently, the number of chips that can be produced from a single wafer may be increased to cut the manufacturing cost of the semiconductor device. While it is usually difficult to control crystal defects in a SiC ingot having a large diameter, according to the present embodiment, even a SiC ingot having a diameter of not less than 100 mm, for example, can be manufactured while the crystal quality is maintained. The thickness of SiC seed substrate 10a is about 0.5 to 5.0 mm, for example, and preferably about 0.5 to 2.0 mm.

After the slicing, it is desirable to subject second main surface P2 of SiC seed substrate 10a to polishing, reactive ion etching (RIE) or the like, to planarize the surface. This is to facilitate the formation of uniform metal carbide film 11 on second main surface P2. Diamond abrasive grains can be used, for example, for the polishing. A measure of the planarization is about not more than 1 μm in terms of arithmetic mean roughness Ra, for example. It is more preferable to further perform chemical mechanical polishing (CMP) since the degree of planarization is increased as a result. Coloidal silica is used, for example, for the CMP.

Here, to improve the crystal quality of SiC single crystal 100, first main surface P1 may also be subjected to a similar planarization process. The planarization process on first main surface P1 may be done after the formation of metal carbide film 11 to be described below.

<Step of Forming Metal Carbide Film: S200>

In this step, metal carbide film 11 is formed on second main surface P2 at a temperature of not more than 2000° C. The temperature is limited to not more than 2000° C. because SiC may be sublimated to roughen the surface of SiC seed substrate 10a if the temperature exceeds 2000° C.

(Metal Carbide Film)

It is desirable for metal carbide film 11 to be able to be formed at not more than 2000° C., and to be formed of a material having a melting point exceeding the temperature during crystal growth of SiC (2100° C. to 2500° C.) after being formed. It is further desirable for metal carbide film 11 to be a dense film with a low number of voids therein. This is to suppress the backside sublimation during crystal growth. Examples of materials satisfying these conditions include a carbide of high melting point metal. More specifically, the examples include TiC, VC and ZrC. Metal carbide film 11 may be formed of one type of material, or two or more types of materials, selected from TiC, VC and ZrC. When formed of two or more types of materials, Ti, V and C, for example, may form a composite compound. Moreover, metal carbide film 11 may be single layer, or a laminate of a plurality of layers. This is because the backside sublimation can be suppressed in either case. That is, metal carbide film 11 may include at least one of TiC, VC and ZrC.

When a compound is expressed by a chemical formula such as “TiC, VC and ZrC” in the present specification, any conventionally known atomic ratios are to be included without being necessarily limited to those within a stoichiometric range, unless the atomic ratio is particularly limited. For example, the term “TiC” is not limited to have an atomic ratio of 50:50 between “Ti” and “C”, but includes any conventionally known atomic ratios.

Metal carbide film 11 may be formed by depositing a metal element (Ti, V and Zr, for example) and carbon (C) on second main surface P2 by chemical vapor deposition (CVD), sputtering and the like, for example, or may be formed by forming metal film 11a first and then carbonizing metal film 11a, as will be described below.

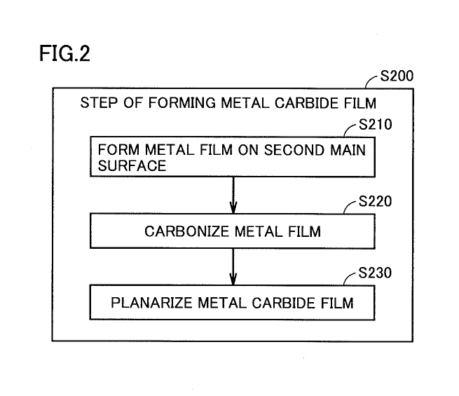

FIG. 2 is a flowchart showing an example of the step of forming metal carbide film 11 (S200). As shown in FIG. 2, this step (S200) can include, for example, a step of forming metal film 11a on second main surface P2 (S210), and a step of carbonizing metal film 11a (S220). This step can further include, after the step of carbonizing metal film 11a (S220), a step of planarizing metal carbide film 11 (S230). These steps can be performed, for example, in a growth container 50 (a crucible, for example) used during crystal growth. The manufacturing process can be simplified in such a mode.

(Step of Forming Metal Film: S210)

In this step, metal film 11a is formed on second main surface P2. For example, a metal plate having an appropriate thickness corresponding to metal film 11a may be prepared, and placed on second main surface P2. Alternatively, metal film 11a may be formed on second main surface P2 by CVD, sputtering and the like.

(Step of Carbonizing Metal Film: S220)

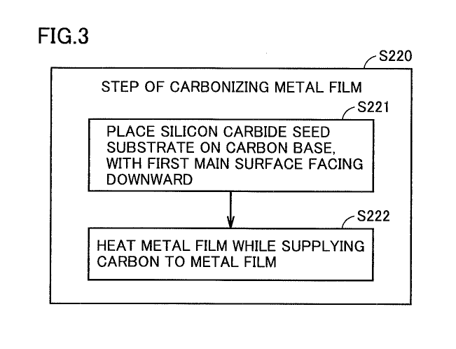

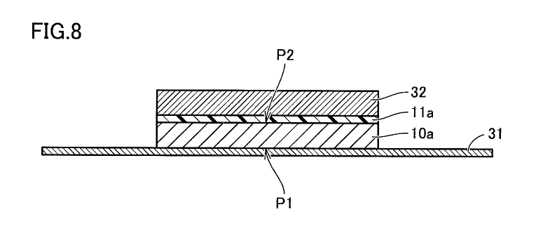

Metal film 11a is then carbonized. FIG. 3 is a flowchart showing a suitable operation procedure in this step (S220). FIG. 8 is a schematic cross-sectional view illustrating the operation.

As shown in FIGS. 3 and 8, it is preferable to first perform a step of placing SiC seed substrate 10a on a carbon base 31, with first main surface P1 facing downward (S221). This is to suppress the surface roughness of first main surface P1. Carbon base 31 is not particularly limited, but is preferably a highly flexible material such as a carbon sheet. This is because first main surface P1 can be protected.

Then, a step of heating metal film 11a while supplying carbon to metal film 11a (S222) is performed. Here, the carbon may be supplied in any form. For example, carbon in gaseous form, powder form, sheet form or plate form may be supplied. The heating temperature is not less than the melting point of metal film 11a and not more than 2000° C., for example. The heating atmosphere is preferably a vacuum atmosphere (reduced-pressure atmosphere) or an atmosphere of inert gas such as argon (Ar). Then, metal film 11a is maintained for about 1 to 24 hours at a target temperature, which has been set within the range of not less than the melting point of metal film 11a and not more than 2000° C., to thereby form metal carbide film 11.

When metal film 11a is a metal plate and the carbon is supplied in plate form as shown in FIG. 8, an appropriate load may be applied from above a carbon plate 32 to bring metal film 11a and carbon plate 32 in close contact with each other so as not to create a gap between them. Consequently, uniform metal carbide film 11 can be obtained, and metal carbide film 11 can be strongly adhered to second main surface P2. To apply the load, a weight may be placed on carbon plate 32, for example. Here, the weight is preferably a non-heatable body.

As described above, metal carbide film 11 may be planarized after being formed. Excessive carbon can thus be reduced. The film thickness and film thickness distribution of metal carbide film 11 can also be adjusted. Specifically, the surface of metal carbide film 11 can be dry etched by RIE and the like or polished by CMP and the like, for example.

(Film Thickness of Metal Carbide Film)

It is preferable that the film thickness of metal carbide film 11 be not less than 0.1 μm and not more than 1.0 mm. If the film thickness is less than 0.1 μm, the backside sublimation may not be sufficiently suppressed. On the other hand, since 1.0 mm is enough to provide the function of suppressing the sublimation, it is not economical for the film thickness to exceed 1.0 mm. However, it is acceptable for the film thickness to exceed 1.0 mm so long as the economic efficiency is ignored. The film thickness of metal carbide film 11 is more preferably not less than 1.0 μm and not more than 1.0 mm, further preferably not less than 10 μm and not more than 1.0 mm, and most preferably not less than 100 μm and not more than 1.0 mm. This is to enhance the effect of suppressing the backside sublimation.

(Coefficient of Variation of Film Thickness)

It is preferable that a coefficient of variation of the film thickness of metal carbide film 11 be not more than 20%. This is because a narrower temperature distribution in metal carbide film 11 is obtained during crystal growth, thereby reducing the occurrence and concentration of thermal stress. The “coefficient of variation of the film thickness” as used herein refers to an index of film thickness distribution, which is a value expressed as a percentage obtained by dividing the standard deviation of the film thickness by the average value of the film thickness. To calculate the coefficient of variation, the film thickness is to be measured at a plurality of locations (at least five locations, preferably ten or more locations, and more preferably twenty or more locations). The film thickness can be measured by conventionally known means. For example, a Fourier transform infrared spectrometer (FT-IR) may be used. Such a coefficient of variation is more preferably not more than 18%, and particularly preferably not more than 15%. This is to reduce the occurrence of thermal stress.

<Silicon Carbide Seed Substrate>

Through the step (S100) and step (S200) described above, SiC seed substrate 10a that can be utilized for the manufacturing method of the present embodiment is prepared. As shown in FIG. 4, SiC seed substrate 10a includes first main surface P and second main surface P2 located opposite first main surface P1. Here, first main surface P1 is a crystal growth surface, and second main surface P2 which is a backside surface thereof has metal carbide film 11 formed thereon. As described above, metal carbide film 11 can include at least one of TiC, VC and ZrC.

<Method of Growing Silicon Carbide Single Crystal: S300>

In this step, SiC single crystal 100 is grown on SiC seed substrate 10a by using SiC seed substrate 10a having metal carbide film 11.

As shown in FIG. 4, growth container 50 including a supporting member 51a and a container body 52 is prepared. Growth container 50 is made of graphite, for example. Container body 52 contains powders of a pulverized SiC polycrystal, for example, as a source material 1. Supporting member 51a also functions as a lid of growth container 50. Supporting member 51a is provided with a supporting portion ST for supporting SiC seed substrate 10a. SiC seed substrate 10a is disposed above and at a distance from source material 1, such that first main surface P1 serving as the growth surface faces source material 1.

Here, SIC seed substrate 10a is supported, at a supported portion SD at the end of first main surface P1, by supporting portion ST. That is, supported portion SD of the surface of SiC seed substrate 10a supported by supporting member 51a is in a region other than the region where metal carbide film 11 has been formed. There is thus a gap between metal carbide film 11 and supporting member 51a, and the second main surface P2 side of SiC seed substrate 10a is not constrained. While a heat sink, a heating element or the like may be inserted into this gap so as to maintain the temperature environment during crystal growth, it is desirable to minimize the degree of constraint on SiC seed substrate 10a in that case. It is also preferable to not fix supporting portion ST and supported portion SD to each other by fitting, adhesion or the like, so as not to hinder the free expansion of SiC seed substrate 10a. That is, it is preferable to simply place SiC seed substrate 10a on supporting portion ST.

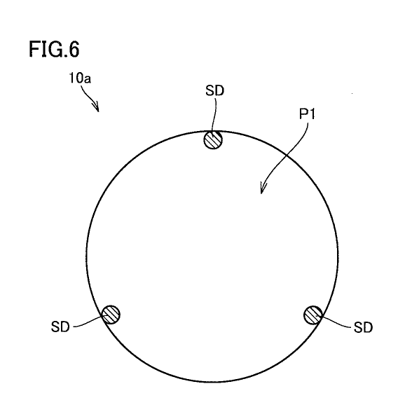

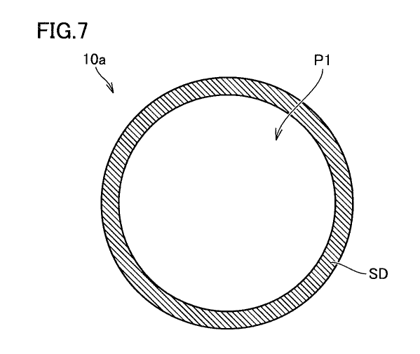

FIG. 6 is a schematic plan view illustrating an example of supported portions SD on first main surface P1. As shown in FIG. 6, it is preferable that there be at least three supported portions SD. This is to stabilize the posture of SiC seed substrate 10a. FIG. 7 is a schematic plan view illustrating another example of supported portion SD on first main surface P1. As shown in FIG. 7, it is more preferable to provide supported portion SD so as to surround the outer circumference of SiC seed substrate 10a. This is because the posture of SiC seed substrate 10a can be maintained in a more stabilized manner.

Then, as shown in FIG. 4, SiC single crystal 100 is grown by sublimation. That is, source material 1 is sublimated in a direction of arrows in FIG. 4 and the sublimate is deposited on first main surface P1, by setting appropriate temperature and pressure conditions in growth container 50. Here, the temperature condition is preferably not less than 2100° C. and not more than 2500° C., and the pressure condition is preferably not less than 1.3 kPa and not more than the atmospheric pressure. The pressure condition may further be not more than 13 kPa so as to increase the growth rate.

In the present embodiment, the second main surface P2 side of SiC seed substrate 10a is not constrained as described above. Thus, SiC seed substrate 10a can thermally expand freely during growth of SiC single crystal 100. Accordingly, the thermal stress that occurs in SiC seed substrate 10a and SiC single crystal 100 in the conventional manufacturing method is relieved. Furthermore, the sublimation from second main surface P2 can be suppressed by metal carbide film 11. Therefore, the SiC ingot with a low number of crystal defects can be manufactured.

[Variation]

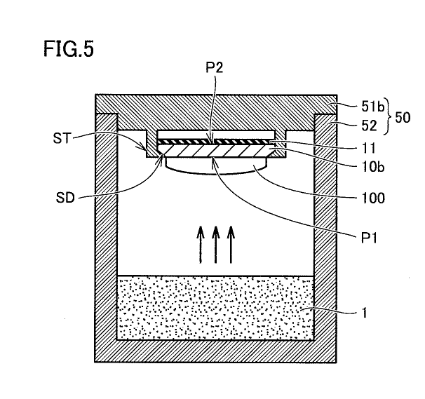

A variation of the method of manufacturing the SiC ingot is now described. FIG. 5 is a schematic cross-sectional view illustrating a step of growing SiC single crystal 100 according to the variation. As shown in FIG. 5, a SiC seed substrate 10b having a side surface inclined in a tapered shape that connects first main surface P1 and second main surface P2 is used in this variation. Such SiC seed substrate 10b can be prepared by, for example, grinding a SiC ingot into a cylindrical shape, then slicing the SiC ingot to obtain a substrate, and furthermore, chamfering the side surface of the substrate. SiC seed substrate 10b has metal carbide film 11 formed on second main surface P2, as with SiC seed substrate 10a described above.

As shown in FIG. 5, a supporting member 51b also has supporting portion ST inclined in a tapered shape. Thus, SIC seed substrate 10b can be supported by supporting member 51b without requiring special positioning work, leading to a reduced processing load. In addition, supported portion SD is at a portion of the side surface of SiC seed substrate 10b inclined in a tapered shape. That is, again in this case, supported portion SD is in a region of the surface of SiC seed substrate 10b other than the region where metal carbide film 11 has been formed. Accordingly, in a manner similar to above, SiC single crystal 100 can be grown on first main surface P1 with the second main surface P2 side of SiC seed substrate 10b not being constrained, and the backside sublimation is suppressed by metal carbide film 11. Therefore, the SiC ingot with a low number of crystal defects can be manufactured.

<Silicon Carbide Substrate>

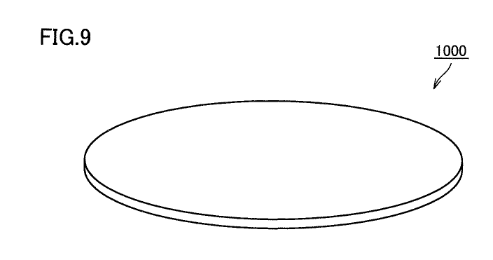

A SiC substrate 1000 according to the present embodiment is described. FIG. 9 is a schematic diagram showing an example of SiC substrate 1000. SiC substrate 1000 is a substrate (wafer) obtained by slicing the SiC ingot which has been obtained with the manufacturing method described above, and is useful as a substrate for a semiconductor device as it has a low number of crystal defects. The thickness of SiC substrate 1000 is not less than 0.2 mm and not more than 5.0 mm, for example. The planar shape of SiC substrate 1000 is circular, for example, and the diameter of SiC substrate 1000 is preferably not less than 100 mm, and more preferably not less than 150 mm. The manufacturing cost of the semiconductor device may be cut consequently.

Having been subjected to the manufacturing process described above, SiC substrate 1000 includes the metal element (Ti, V and Zr, for example) forming metal carbide film 11. However, the element is in a concentration within the range of not less than 0.01 ppm and not more than 0.1 ppm, and is considered to have little influence on the performance of the semiconductor device. The concentration (mass fraction) of the metal element can be measured by secondary ion mass spectrometry (SIMS) or total reflection X-ray fluorescence (TXRF), for example. The concentration of the metal element is preferably not more than 0.09 ppm, more preferably not more than 0.08 ppm, and particularly preferably not more than 0.07 ppm.

<Silicon Carbide Epitaxial Substrate>

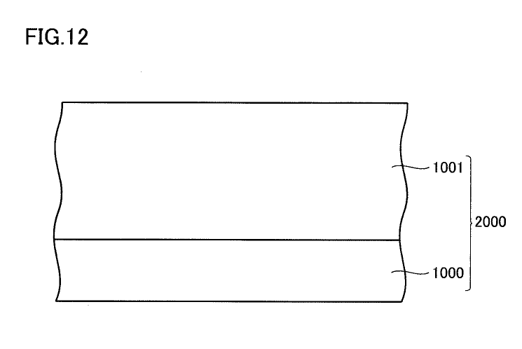

A silicon carbide epitaxial substrate according to the present embodiment is described. FIG. 12 is a schematic cross-sectional view showing an example of the configuration of the silicon carbide epitaxial substrate according to the present embodiment. A SiC epitaxial substrate 2000 includes SiC substrate 1000, and an epitaxial layer 1001 formed on SIC substrate 1000.

SiC substrate 1000 includes at least one selected from the group of metal elements consisting of Ti, V and Zr. In SiC substrate 1000, the concentration of the metal element is not less than 0.01 ppm and not more than 0.1 ppm. Epitaxial layer 1001 is a layer epitaxially grown on SiC substrate 1000. Epitaxial layer 1001 may be a layer made of silicon carbide, or a layer made of a compound different from silicon carbide, such as gallium nitride (GaN). The thickness of epitaxial layer 1001 may be not less than 5 μm, or not less than 10 μm, for example. The thickness of epitaxial layer 1001 may be not more than 100 μm, or not more than 50 μm, for example.

As described above, SiC substrate 1000 is a substrate with a low number of crystal defects. Accordingly, epitaxial layer 1001 grown on SiC substrate 1000 can also be a layer with a low number of crystal defects.

[Semiconductor Device]

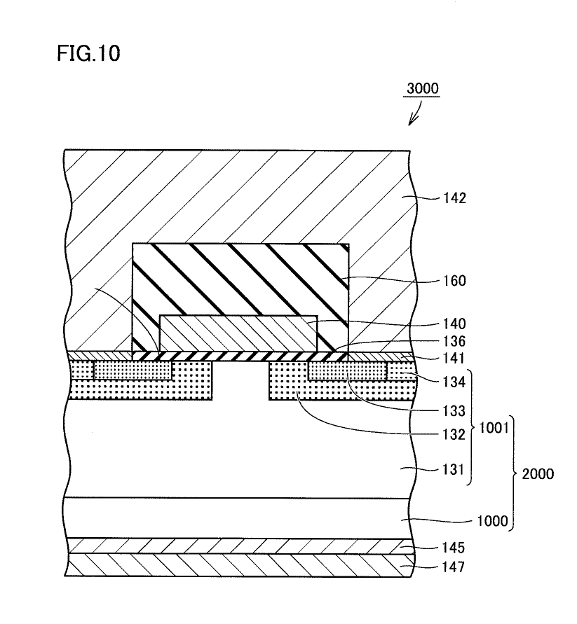

A semiconductor device according to the present embodiment device is described. FIG. 10 is a schematic cross-sectional view showing an example of the configuration of the semiconductor device according to the present embodiment. The semiconductor device shown in FIG. 10 is a MOSFET (metal-oxide-semiconductor field effect transistor).

A MOSFET 3000 includes SiC epitaxial substrate 2000. MOSFET 3000 further includes a gate oxide film 136, a gate electrode 140, an interlayer insulating film 160, a source electrode 141, a surface protecting electrode 142, a drain electrode 145, and a backside surface protecting electrode 147.

As described above, SiC epitaxial substrate 2000 includes SiC substrate 1000, and epitaxial layer 1001 formed on SiC substrate 1000. That is, MOSFET 3000 is a semiconductor device including a SiC substrate including at least one selected from the group of metal elements consisting of Ti, V and Zr, the concentration of the metal element being not less than 0.01 ppm and not more than 0.1 ppm.

In MOSFET 3000, SiC substrate 1000 is an n type substrate having n type conductivity (first conductivity type). Epitaxial layer 1001 is provided on SiC substrate 1000. In MOSFET 3000, epitaxial layer 1001 is a homoepitaxial layer made of silicon carbide. Epitaxial layer 1001 includes, for example, a drift region 131, a body region 132, a source region 133, and a contact region 134. Drift region 131 contains an n type impurity such as nitrogen (N), and has n type conductivity. The concentration of the n type impurity in drift region 131 may be lower than the concentration of then type impurity in SiC substrate 1000. Body region 132 contains a p type impurity such as aluminum (Al) or boron (B), and has p type conductivity (second conductivity type different from the first conductivity type). The concentration of the p type impurity in body region 132 may be higher than the concentration of the n type impurity in drift region 131.

The “first conductivity type” and “second conductivity type” in the present specification are used solely to distinguish the first conductivity type and second conductivity type from each other. Thus, the first conductivity type may be p type and the second conductivity type may be n type.

Source region 133 contains an impurity such as phosphorus (P), and has n type conductivity. Source region 133 is separated from drift region 131 by body region 132. Source region 133 forms a portion of the surface of epitaxial layer 1001. Source region 133 may be surrounded by body region 132 when seen from a direction perpendicular to the surface of epitaxial layer 1001. The concentration of the n type impurity in source region 133 may be higher than the concentration of the n type impurity in drift region 131.

Contact region 134 contains a p type impurity such as Al, B, and has p type conductivity. Contact region 134 forms a portion of the surface of epitaxial layer 1001. Contact region 134 extends through source region 133, and is in contact with body region 132. The concentration of the p type impurity in contact region 134 may be higher than the concentration of the p type impurity in body region 132.

Gate oxide film 136 is formed on the surface of epitaxial layer 1001. Gate oxide film 136 is in contact with each of source region 133, body region 132 and drift region 131. Gate oxide film 136 may be made of silicon dioxide, for example.

Gate electrode 140 is provided on gate oxide film 136. Gate electrode 140 faces each of source region 133, body region 132 and drift region 131. Gate electrode 140 may be made of polysilicon doped with an impurity, Al, for example.

Source electrode 141 is in contact with source region 133 and contact region 134. Source electrode 141 may be in contact with gate oxide film 136. Source electrode 141 may be made of a material including Ti, Al and Si, for example. Source electrode 141 may be in ohmic contact with source region 133. Source electrode 141 may also be in ohmic contact with contact region 134.

Interlayer insulating film 160 covers gate electrode 140. Interlayer insulating film 160 is in contact with gate electrode 140 and gate oxide film 136. Interlayer insulating film 160 electrically insulates gate electrode 140 and source electrode 141 from each other. Surface protecting electrode 142 covers interlayer insulating film 160. Surface protecting electrode 142 may be made of a material including Al, for example. Surface protecting electrode 142 is electrically connected to source electrode 141.

Drain electrode 145 is in contact with SiC substrate 1000. Drain electrode 145 may be in ohmic contact with SiC substrate 1000. Drain electrode 145 and epitaxial layer 1001 face each other, with SiC substrate 1000 interposed therebetween. Drain electrode 145 may be made of a material including NiSi, for example. Backside surface protecting electrode 147 is electrically connected to drain electrode 145. Backside surface protecting electrode 147 may be made of a material including Al, for example.

<Method of Manufacturing Semiconductor Device>

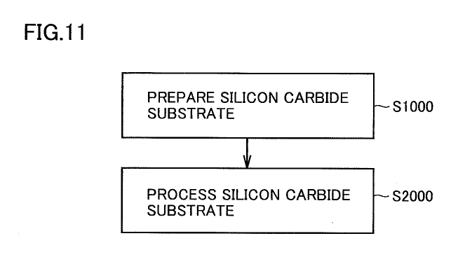

A method of manufacturing the semiconductor device according to the present embodiment is described. By way of example, a method of manufacturing MOSFET 3000 noted above is described here. FIG. 11 is a flowchart showing an overview of the method of manufacturing the semiconductor device according to the present embodiment. The method of manufacturing the semiconductor device includes a step of preparing a silicon carbide substrate (S1000), and a step of processing the silicon carbide substrate (S2000). The step of preparing a SiC substrate has already been described and thus will not be repeated here.

(Step of Processing Silicon Carbide Substrate: S2000)

After the SiC substrate has been prepared, the step of processing the SiC substrate is performed. The step of processing the SiC substrate in the present embodiment includes, for example, epitaxial growth on the SiC substrate, electrode formation on the SiC substrate, and dicing of the SiC substrate. That is, the step of processing the SiC substrate may be a step including at least one of an epitaxial growth step, an electrode formation step and a dicing step.

As shown in FIG. 12, first, epitaxial layer 1001 made of silicon carbide is grown on SiC substrate 1000 by CVD, for example. SiC epitaxial substrate 2000 is thus manufactured. Silane (SiH₄) and propane (C₃H₈), for example, are used as a source material gas for the epitaxial growth. Hydrogen (H₂), for example, is used as a carrier gas. The temperature of SiC substrate 1000 during the epitaxial growth may be about not less than 1400° C. and not more than 1700° C., for example.

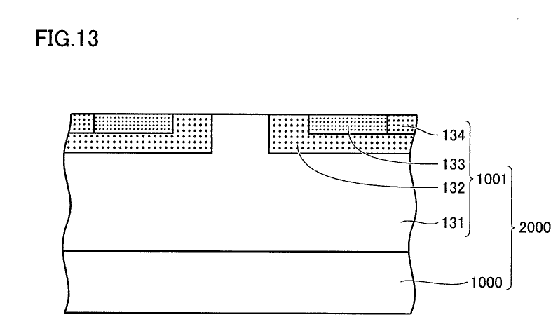

After the epitaxial growth, ion implantations are performed. FIG. 13 is a schematic cross-sectional view illustrating the ion implantation step. Al ions, for example, are implanted into the surface of epitaxial layer 1001. Body region 132 having p type conductivity is thus formed in epitaxial layer 1001. Subsequently, P ions, for example, are implanted into body region 132 to a depth shallower than the implantation depth of the above Al ions. Source region 133 having n type conductivity is thus formed. Furthermore, Al ions, for example, are implanted into source region 133. Contact region 134 extending through source region 133 and reaching body region 132, and having p type conductivity is thus formed. In epitaxial layer 1001, a region other than body region 132, source region 133 and contact region 134 serves as drift region 131. The temperature of SiC epitaxial substrate 2000 during the ion implantations may be about 300 to 600° C., for example.

After the ion implantations, activation annealing is performed. SiC epitaxial substrate 2000 is subjected to heat treatment for about 30 minutes at a temperature of about 1800° C., for example. This activates the impurities introduced by the ion implantations, to generate desired carriers in each region.

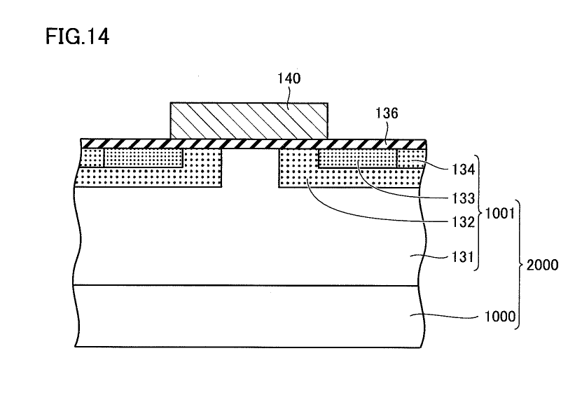

After the activation annealing, a gate oxide film is formed. FIG. 14 is a schematic cross-sectional view illustrating a gate oxide film formation step and an electrode formation step. The gate oxide film is formed by thermal oxidation, for example. The thermal oxidation is effected by subjecting SiC epitaxial substrate 2000 to heat treatment under an atmosphere including oxygen. The gate oxide film made of silicon dioxide can thus be formed. The heat treatment temperature may be about 1300° C., for example. The heat treatment time may be about 60 minutes, for example. Gate oxide film 136 is formed so as to be in contact with each of drift region 131, body region 132, source region 133 and contact region 134, on the surface of epitaxial layer 1001.

Then, a gate electrode is formed on the gate oxide film. The gate electrode is formed by LPCVD (low pressure CVD), for example. Gate electrode 140 is made of polysilicon doped with an impurity and exhibiting a conductive property, for example. Gate electrode 140 is formed in a position facing each of source region 133, body region 132 and drift region 131.

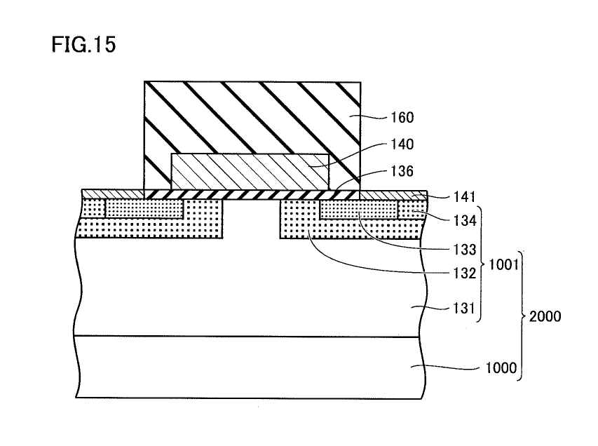

Then, an interlayer insulating film is formed. FIG. 15 is a schematic cross-sectional view illustrating an interlayer insulating film formation step and an electrode formation step. The interlayer insulating film is formed by plasma CVD, for example. The interlayer insulating film is made of a material including silicon dioxide, for example. Interlayer insulating film 160 is formed so as to cover gate electrode 140 and to be in contact with gate oxide film 136.

Then, a source electrode is formed. Prior to the formation of the source electrode, interlayer insulating film 160 and gate oxide film 136 are partially etched. A region where source region 133 and contact region 134 are exposed through gate oxide film 136 is thus formed. Then, on the region where source region 133 and contact region 134 are now exposed, a metal layer is formed by sputtering, for example. The metal layer is made of a material including Ti, Al and Si, for example. The metal layer is subjected to heat treatment at about 1000° C., for example, to silicide at least a portion of the metal layer. The metal layer now serves as source electrode 141 in ohmic contact with source region 133.

Then, a surface protecting electrode is formed. The surface protecting electrode is formed by sputtering, for example. The surface protecting electrode may be made of a material including Al, for example. As shown in FIG. 10, surface protecting electrode 142 is formed so as to be in contact with source electrode 141 and to cover interlayer insulating film 160.

Then, a drain electrode is formed. The drain electrode is formed by sputtering, for example. As shown in FIG. 10, drain electrode 145 is formed in a position facing epitaxial layer 1001, with SiC substrate 1000 interposed therebetween. Drain electrode 145 is made of a material including NiSi, for example. Backside surface protecting electrode 147 is further formed in contact with drain electrode 145. The backside surface protecting electrode is formed by sputtering, for example. The backside surface protecting electrode is made of a material including Al, for example.

Furthermore, SiC substrate 1000 is divided by a prescribed dicing blade. Semiconductor devices as a plurality of chips are thus manufactured.

As noted above, the MOSFET has been described as an example of the semiconductor device in the present specification. However, the semiconductor device of the present embodiment is not limited to the MOSFET. The present embodiment may be applied to an IGBT (insulated gate bipolar transistor), an SBD (Schottky barrier diode), an LED (light emitting diode), a JFET (junction field effect transistor), a thyristor, a GTO (gate turn-off thyristor), a PiN diode, a MESFET (metal-semiconductor field effect transistor), for example.

These semiconductor devices are not limited to a silicon carbide semiconductor device, as long as they include the silicon carbide substrate of the present embodiment. For example, the semiconductor device of the present embodiment may include, on the silicon carbide substrate, an epitaxial layer made of a compound different from silicon carbide, such as GaN.

The conductivity type of SiC substrate 1000 can be changed appropriately depending on the applied semiconductor device, device specification, and the like. SiC substrate 1000 may be an n type substrate, a p type substrate, or a semi-insulating substrate.

In the step of growing the SiC single crystal (S300) noted above, by introducing N₂ gas, phosphine (PH₃) gas, for example, into growth container 50, nitrogen, phosphorus or the like which is an n type impurity can be incorporated into the single crystal, whereby a SiC single crystal having 11 type conductivity can be manufactured. An n type substrate is obtained by slicing this SiC single crystal.

By introducing a solid or gas containing a p type impurity such as Al, B into growth container 50, Al, B or the like which is a p type impurity can be incorporated into the single crystal, whereby a SiC single crystal having p type conductivity can be manufactured. A p type substrate is obtained by slicing this SiC single crystal. Examples of the solid or gas containing a p type impurity include metal Al, trimethylaluminum ((CH₃)₃Al) gas, boron trichloride (BCl₃) gas.

In addition, by growing a single crystal in an atmosphere having a reduced n type impurity and p type impurity, a semi-insulating SiC single crystal can be manufactured. A semi-insulating substrate is obtained by slicing this SiC single crystal. The atmosphere having a reduced n type impurity and p type impurity can be formed as follows, for example. That is, members made of graphite and placed in a furnace, including growth container 50, are subjected to heat treatment, halogen treatment and the like in advance, to minimize nitrogen, phosphorus, Al, B and the like included in the members made of graphite. By using the members made of graphite having a minimized n type impurity and p type impurity, and by not substantially introducing an n type impurity and p type impurity into the introduced gas, an atmosphere in which the SiC single crystal can be semi-insulating can be formed.

Although the present embodiment has been described above, it should be understood that embodiments disclosed herein are illustrative and non-restrictive in every respect. The scope of the present invention is defined by the terms of the claims, rather than the embodiments described above, and is intended to include any modifications within the scope and meaning equivalent to the terms of the claims.

### REFERENCE SIGNS LIST

1 source material; 10a, 10b silicon carbide seed substrate; 11 metal carbide film; 11a metal film; 31 carbon base; 32 carbon plate; 50 growth container; 51a, 51b supporting member; 52 container body; 100 silicon carbide single crystal; 131 drift region; 132 body region; 133 source region; 134 contact region; 136 gate oxide film; 140 gate electrode; 141 source electrode; 142 surface protecting electrode; 145 drain electrode; 147 backside surface protecting electrode; 160 interlayer insulating film; 1000 silicon carbide substrate (substrate for semiconductor device); 1001 epitaxial layer; 2000 silicon carbide epitaxial substrate; 3000 MOSFET (semiconductor device); P1 first main surface; P2 second main surface; SD supported portion; ST supporting portion.

1: A method of manufacturing a silicon carbide ingot, comprising the steps of:
preparing a silicon carbide seed substrate having a first main surface and a second main surface located opposite the first main surface;
forming a metal carbide film on the second main surface at a temperature of not more than 2000° C.; and
growing a silicon carbide single crystal on the first main surface by sublimation, while supporting the silicon carbide seed substrate having the metal carbide film formed thereon by a supporting member,
in the growing step, a supported portion of the surface of the silicon carbide seed substrate supported by the supporting member being in a region other than a region where the metal carbide film has been formed.

2: The method of manufacturing a silicon carbide ingot according to claim 1, wherein
the metal carbide film includes at least one of titanium carbide, vanadium carbide and zirconium carbide.

3: The method of manufacturing a silicon carbide ingot according to claim 1, wherein
the step of forming a metal carbide film includes the steps of
forming a metal film on the second main surface, and
carbonizing the metal film.

4: The method of manufacturing a silicon carbide ingot according to claim 3, wherein
the step of carbonizing the metal film includes the steps of
placing the silicon carbide seed substrate on a carbon base, with the first main surface facing downward, and
heating the metal film while supplying carbon to the metal film.

5: The method of manufacturing a silicon carbide ingot according to claim 3, wherein
the step of forming a metal carbide film further includes the step of, after the step of carbonizing the metal film, planarizing the metal carbide film.

6: The method of manufacturing a silicon carbide ingot according to claim 1, wherein
in the growing step,
the silicon carbide seed substrate is disposed above and at a distance from the source material,
the first main surface faces the source material, and
the supported portion is at the end of the first main surface.

7: A silicon carbide seed substrate, comprising a first main surface and a second main surface located opposite the first main surface,
the first main surface being a crystal growth surface,
the second main surface having a metal carbide film thereon,
the metal carbide film including at least one of titanium carbide, vanadium carbide and zirconium carbide.

8: The silicon carbide seed substrate according to claim 7, wherein
a film thickness of the metal carbide film is not less than 0.1 μm and not more than 1.0 mm.

9: The silicon carbide seed substrate according to claim 7, wherein
a coefficient of variation of the film thickness of the metal carbide film is not more than 20%.

10: A method of manufacturing a silicon carbide ingot, comprising the steps of:
preparing the silicon carbide seed substrate according to claim 7; and
growing a silicon carbide single crystal on the first main surface by sublimation, while supporting the silicon carbide seed substrate by a supporting member,
in the growing step, a supported portion of the surface of the silicon carbide seed substrate supported by the supporting member being in a region other than a region where the metal carbide film has been formed.

11: A silicon carbide substrate, obtained by slicing the silicon carbide ingot which has been obtained with the manufacturing method according to claim 10,
the substrate including a metal element forming the metal carbide film,
a concentration of the metal element being not less than 0.01 ppm and not more than 0.1 ppm.

12: A semiconductor device, comprising a silicon carbide substrate including at least one selected from the group of metal elements consisting of titanium, vanadium and zirconium, a concentration of the metal element being not less than 0.01 ppm and not more than 0.1 ppm.

13: The semiconductor device according to claim 12, wherein
the silicon carbide substrate is a semi-insulating substrate.

14: The semiconductor device according to claim 12, wherein
the silicon carbide substrate is an n type substrate.

15: The semiconductor device according to claim 12, wherein
the silicon carbide substrate is a p type substrate.

16: A method of manufacturing a semiconductor device, comprising the steps of:
preparing the silicon carbide substrate according to claim 11; and
processing the silicon carbide substrate.
